(19) United States
(12) Patent Application Publication
(10) Pub. No.: US 2026/0248014 A1
(43) Pub. Date: Aug. 20, 2026

(54) CONNECTION STRUCTURE AND SEMICONDUCTOR DEVICE COMPRISING THE SAME

(71) Applicant: Samsung Electronics Co., Ltd., Suwon-si (KR)

(72) Inventors: Hyun Hee LEE, Suwon-si (KR); Tae Hyeong KIM, Suwon-si (KR)

(21) Appl. No.: 19/314,722

(22) Filed: Aug. 29, 2025

(30) Foreign Application Priority Data
Feb. 19, 2025 (KR) 10-2025-0021294

(51) Int. Cl. H10W 72/20; H10W 72/90; H10W 72/00; H10W 90/00

(52) U.S. Cl. CPC H10W 72/20; H10W 72/90; H10W 72/07255; H10W 72/252; H10W 72/2528; H10W 72/923; H10W 72/952; H10W 90/00; H10W 90/722

(57) ABSTRACT

A connection structure with improved reliability by preventing volume shrinkage of a solder bump may include a pad containing nickel, a bump connection layer containing nickel, and a solder bump arranged between the pad and the bump connection layer. The solder bump may include a first intermetallic compound contacting the pad and containing copper, and a second intermetallic compound contacting the bump connection layer and containing copper.

### CROSS-REFERENCE TO RELATED APPLICATION

This application claims priority from Korean Patent Application No. 10-2025-0021294 filed on February 19, 2025 in the Korean Intellectual Property Office, the contents of which in its entirety are herein incorporated by reference.

### BACKGROUND

### Technical Field

The present disclosure relates to a connection structure and a semiconductor device comprising the same.

### DESCRIPTION OF THE RELATED ART

A solder bump may be used to electrically connect a plurality of semiconductor devices, which are stacked, to each other. For example, a pad is formed in a first semiconductor device, and a bump base and a solder bump are formed in a second semiconductor device. The solder bump is positioned between the pad and the bump base, and as the solder bump is positioned through a thermal process, the solder bump electrically connects the pad with the bump base.

As an intermetallic compound (IMC) is generated in the solder bump during a subsequent process/test, a volume of the solder bump shrinks or a void may occur in the solder bump.

### BRIEF SUMMARY

An objective of the present disclosure is to provide a connection structure with improved reliability by preventing volume shrinkage of a solder bump.

Another objective of the present disclosure is to provide a semiconductor device with improved reliability by preventing volume shrinkage of a solder bump.

Still another objective of the present disclosure is to provide a manufacturing method of a connection structure with improved reliability by preventing volume shrinkage of a solder bump.

The objectives of the present disclosure are not limited to those mentioned above and additional objectives, which are not mentioned herein, will be clearly understood by those skilled in the art from the following description of the present disclosure.

A conductive interconnection node for a semiconductor device according to some embodiments of the present disclosure comprises a pad containing nickel, a bump connection layer containing nickel, and a solder bump arranged between the pad and the bump connection layer. The solder bump includes a first intermetallic compound contacting the pad and containing copper, and a second intermetallic compound contacting the bump connection layer and containing copper.

A semiconductor device according to some embodiments of the present disclosure comprises a first substrate; a second substrate arranged on the first substrate; and a conductive interconnection node electrically connecting the first substrate to the second substrate. The conductive interconnection node includes a pad formed in the first substrate and containing nickel, a bump connection layer formed in the second substrate and containing nickel, and a solder bump arranged between the pad and the bump connection layer. The solder bump includes a first intermetallic compound contacting the pad and containing copper, and a second intermetallic compound contacting the bump connection layer and containing copper.

A semiconductor device according to some embodiments of the present disclosure comprises a package substrate, a logic die arranged on the package substrate, a plurality of memory dies sequentially stacked on the logic die, wherein the plurality of memory dies include a first die and a second die, which are stacked; and a conductive connection node between and electrically connecting the first die to the second die. The conductive connection node includes a pad formed in the first die and containing nickel, a bump connection layer formed in the second die and containing nickel, and a solder bump arranged between the pad and the bump connection layer. The solder bump includes a first intermetallic compound portion including a first intermetallic compound including copper and contacting the pad, and a second intermetallic compound portion including the first intermetallic compound including copper or a second intermetallic compound including iron or lead, and contacting the bump interconnection layer.

A manufacturing method of a connection structure according to some embodiments comprises: preparing a pad base containing nickel and a pad structure including a contact layer arranged on the pad base and a first anti-shrinkage layer arranged on the pad base, preparing a bump structure including a bump base containing nickel, a second anti-shrinkage layer arranged on the bump base, and a preliminary solder bump arranged on the second anti-shrinkage layer, and performing annealing through contact between the pad structure and the bump structure, wherein, as a result of annealing, a solder bump is formed that includes a first intermetallic compound contacting a pad formed from the pad base, and a second intermetallic compound contacting a bump connection layer formed from the bump base.

In some embodiments, the first anti-shrinkage layer has a faster permeation rate into the preliminary solder bump than the permeation rate of nickel into the preliminary solder bump.

In some embodiments, the first anti-shrinkage layer contains at least one of copper (Cu), iron (Fe) or lead (Pb).

In some embodiments, the pad base has a thickness thicker than that of the first anti-shrinkage layer.

In some embodiments, the thickness of the first anti-shrinkage layer is 1% to 40% of the thickness of the pad base.

In some embodiments, the thickness of the pad base may be 1μm to 2μm, and the thickness of the first anti-shrinkage layer may be 0.1μm to 0.8μm.

Details of the other embodiments are included in the detailed description and drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a view illustrating a connection structure according to some embodiments of the present disclosure;

FIG. 2 is a view illustrating a connection structure according to some embodiments of the present disclosure;

FIG. 3 is a view illustrating a connection structure according to some embodiments of the present disclosure;

FIG. 4 is a view illustrating a connection structure according to some embodiments of the present disclosure;

FIG. 5 is a cross-sectional view illustrating a connection structure according to some embodiments of the present disclosure;

FIG. 6 is a view illustrating a semiconductor device according to some embodiments of the present disclosure;

FIG. 7 is a plan view illustrating arrangement of the connection structure of FIG. 6;

FIG. 8 is a cross-sectional view illustrating a semiconductor package according to some embodiments of the present disclosure;

FIG. 9 is a flow chart illustrating a method for fabricating a connection structure according to some embodiments of the present disclosure;

FIG. 10 is a view illustrating the method of FIG. 9; and

FIG. 11 is a view illustrating a step S530 of FIG. 9.

### DETAILED DESCRIPTION OF THE DISCLOSURE

Hereinafter, the embodiments according to the present disclosure will be described in detail with reference to the accompanying drawings. The same reference numerals will be used for the same elements on the drawings and a redundant description of the corresponding elements will be omitted.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact.

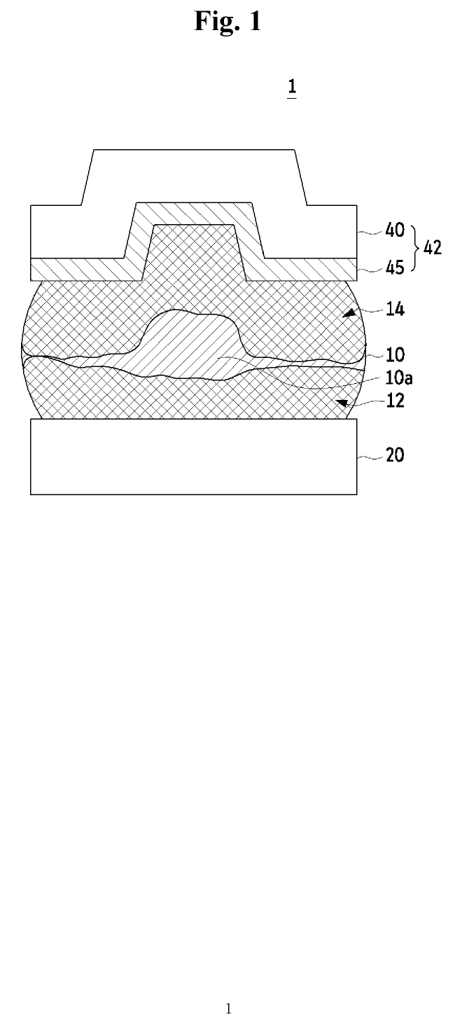

FIG. 1 is a view illustrating a connection structure according to some embodiments of the present disclosure.

Referring to FIG. 1, a connection structure 1 according to some embodiments of the present disclosure may be a conductive connector such as a conductive interconnection node (e.g., interconnection terminal) and includes a pad 20, a bump connection layer 42, and a solder bump 10. The connection structure 1 may be formed within a semiconductor device such as a semiconductor package, for example to electrically connect a package substrate and a semiconductor chip of a semiconductor package.

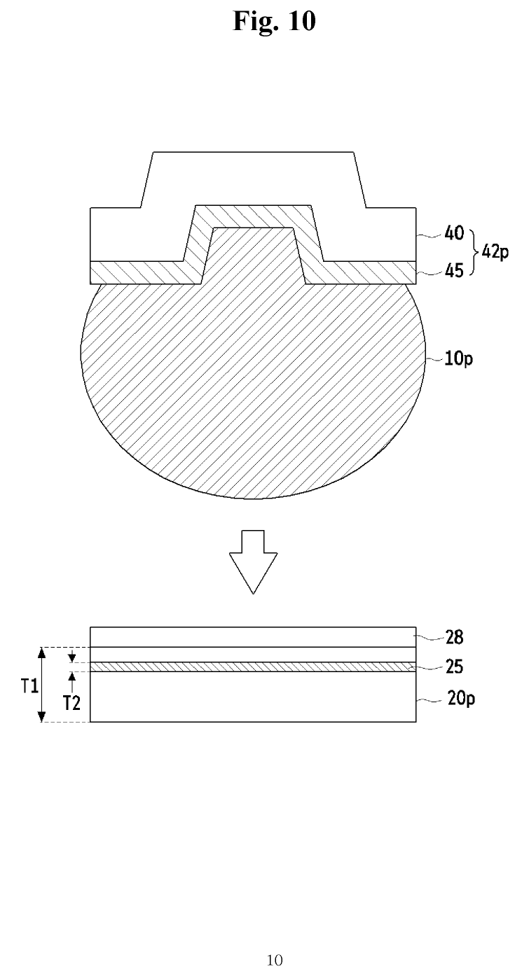

The pad 20 is formed in a first semiconductor device (or a first substrate). For example, in one embodiment, the pad 20 may be formed in or on a first surface of a first semiconductor device (e.g., first semiconductor chip) or substrate, to be exposed with respect to the semiconductor device or substrate. For example, the semiconductor device or substrate may be a semiconductor chip including an insulating layer at an external surface thereof, or may be a substrate such as a package substrate, an interposer, or a printed circuit board (PCB) including an insulating layer at an external surface thereof, and the pad 20 may be formed in the insulating layer. The pad 20 may be made of, for example, Ni, Al, or the like, but is not limited thereto. As will be described later, a portion of a first anti-shrinkage layer (see reference numeral 25 of FIG. 10) used in a process of fabricating the connection structure may remain in the pad 20. The first anti-shrinkage layer may be any one of Cu, Fe, and Pb, for example, but is not limited thereto. Hereinafter, a case in which the first anti-shrinkage layer is a copper layer will be described as an example.

The bump connection layer 42 is formed in a second semiconductor device (or a second substrate). For example, in one embodiment, the bump connection layer 42 may be formed in or on a first surface of a second semiconductor device (e.g., second semiconductor chip) or substrate, to be exposed with respect to the semiconductor device or substrate. For example, the semiconductor device or substrate may be a semiconductor chip including an insulating layer at an external surface thereof, or may be a substrate such as a package substrate, an interposer, or a printed circuit board (PCB) including an insulating layer at an external surface thereof, and the bump connection layer 42 may be formed in and/or on the insulating layer. The bump connection layer 42 may include a bump base 40 and a second anti-shrinkage layer 45. The bump base 40 may be made of, for example, Ni, Al, or the like, but is not limited thereto. As shown, the bump base 40 may be formed along a groove of the second semiconductor device. A second anti-shrinkage layer 45 formed to be conformal along the bump base 40 is positioned on the bump base 40. The second anti-shrinkage layer 45 may be any one of Cu, Fe, and Pb, but is not limited thereto. Hereinafter, a case in which the second anti-shrinkage layer 45 is a copper layer will be described as an example.

The solder bump 10 may contain tin, and for example, may contain Sn, SnAg, Sn-Pb, SnAgZn, SnZn, SnBiIn, SnIn, SnAu, SnZnIn, or SnAgSb, but is not limited thereto. Hereinafter, a case in which the solder bump 10 is made of SnAg will be described as an example.

A first intermetallic compound (IMC) 12 (e.g., first bump intermetallic compound) is formed in the solder bump 10 and contacts the pad 20. The first intermetallic compound 12 contains an anti-shrinkage material. The anti-shrinkage material is obtained, for example, by diffusing a material constituting the first anti-shrinkage layer (see reference numeral 25 of FIG. 10) into a preliminary solder bump to form the solder bump 10. When the anti-shrinkage material is copper, the first intermetallic compound 12 may contain copper, and may be, for example, a copper-tin compound. For example, the first intermetallic compound 12 may be a Cu-Sn-Ag compound.

A second intermetallic compound 14 (e.g., second bump intermetallic compound) is formed in the solder bump 10 and contacts the bump connection layer 42. The second intermetallic compound 14 contains an anti-shrinkage material. The anti-shrinkage material is obtained, for example, by diffusing a material constituting the second anti-shrinkage layer 45 into the preliminary solder bump to form the solder bump 10. When the anti-shrinkage material is copper, the second intermetallic compound 14 may contain copper, and may be, for example, a copper-tin compound. For example, the second intermetallic compound 14 may be a Cu-Sn-Ag compound. The first intermetallic compound 12 and second intermetallic compound 14 may be different portions of the solder bump 10, each containing the same combination of metals. Therefore, a description of a first compound and a second compound is not intended to imply that the compounds are formed of different materials or material compositions, though in some cases, they can have different compositions, such as a different concentrations of copper (or other metal diffused from the first anti-shrinkage material 25 or second anti-shrinkage material 45).

In the solder bump 10, the first intermetallic compound 12 and the second intermetallic compound 14 may be in contact with each other, and/or their boundary may be unclear such that they are merged with each other.

The first intermetallic compound 12 and the second intermetallic compound 14 may be spaced apart from each other in the solder bump 10 depending on process conditions. The solder bump 10 may include the material from the first anti-shrinkage layer 25 in a first region, and the first region constitutes the first intermetallic compound 12. The solder bump 10 may include the material from the second anti-shrinkage layer 45 in a second region, and the second region constitutes the second intermetallic compound 14.

The solder bump 10 may have a region (e.g., a third region) in which the intermetallic compounds 12 and 14 are not formed. For example, when portions of the first intermetallic compound 12 and the second intermetallic compound 14 are in contact with each other or are merged with each other, an intermetallic compound may not be formed in a central region 10a of the solder bump 10. Therefore, in some embodiments, the central region 10a is made of a material (i.e., SnAg) constituting the preliminary solder bump.

Alternatively, when the first intermetallic compound 12 and the second intermetallic compound 14 are not in contact with each other or merged with each other, the intermetallic compound may not be formed in a full-width region between the first intermetallic compound 12 and the second intermetallic compound 14.

As will be described later, a bump structure including the bump connection layer 42 and a preliminary solder bump is heat-treated in contact with the preliminary pad, to form the solder bump 10 bonded to the pad 20. In the heat-treatment process, which may be a reflow process, the first intermetallic compound 12 and the second intermetallic compound 14 are formed in the solder bump 10. For example, according to an example embodiment, in the heat-treatment process, a material (i.e., copper) of the first anti-shrinkage layer 25 is permeated/diffused into a preliminary solder bump to form the first intermetallic compound 12, and a material (i.e., copper) of the second anti-shrinkage layer 45 is permeated/diffused into a preliminary solder bump to form the second intermetallic compound 12.

The material (e.g., copper) constituting the first anti-shrinkage layer 25/the second anti-shrinkage layer 45 has a faster permeation rate than a material (e.g., nickel) constituting the pad base 20p (described below - see FIG. 10)/the bump base 40 (described below – see FIG. 10). Therefore, in the heat-treatment process, copper is diffused into the preliminary solder bump earlier than nickel to form the intermetallic compounds 12 and 14 of solder bump 10. Intermetallic compounds containing nickel are hardly formed in the solder bump 10. The intermetallic compounds 12 and 14 (e.g., copper-tin intermetallic compounds) containing copper are less susceptible to shrinking than intermetallic compounds containing nickel (e.g., nickel-tin intermetallic compounds). Therefore, even though the connection structure is exposed to a high temperature in a subsequent process/test process, the connection structure does not shrink as much. Accordingly, a void does not occur or is smaller or less likely to occur in the connection structure.

In the subsequent process/test process, there is a possibility that the material (e.g., nickel) constituting the pad base 20p may be permeated into the solder bump 10. However, since the intermetallic compounds 12 and 14 containing copper have been already formed in many regions of the solder bump 10, intermetallic compounds containing nickel are less likely to be formed. For example, in some embodiments, even though an intermetallic compound containing nickel is formed, it may be formed only in a very small region. Therefore, according to some embodiments, consumption of the material (e.g., nickel) constituting the pad base 20p is considerably small. Therefore, the amount of nickel in the pad 20 after the subsequent process/test process is not significantly reduced compared to the amount of nickel in the pad base 20p.

A ratio of the intermetallic compounds 12 and 14 containing copper in the solder bump 10 may be 50% or more and 100% or less. For example, a volume ratio of the intermetallic compounds 12 and 14 containing copper to a total volume of the solder bump 10 may be 50% or more and 100% or less. Preferably, the volume ratio may be 60% or more and 100% or less. More preferably, the volume ratio may be 70% or more and 100% or less. The volume ratio of the intermetallic compounds 12 and 14 containing copper to a total volume of the solder bump 10 refers to a ratio of a volume of the solder bump 10 that includes intermetallic compounds that include copper (or whichever material is used in the anti-shrinkage layers 25/45) to the total volume of the solder bump 10. In this way, when the intermetallic compounds 12 and 14 containing copper occupy a large region in the solder bump 10, the connection structure does not shrink significantly even though the connection structure is exposed to a high temperature in the subsequent process/test process.

Since the connection structure according to some embodiments does not shrink significantly and a void is not formed inside, reliability of the connection structure may be improved.

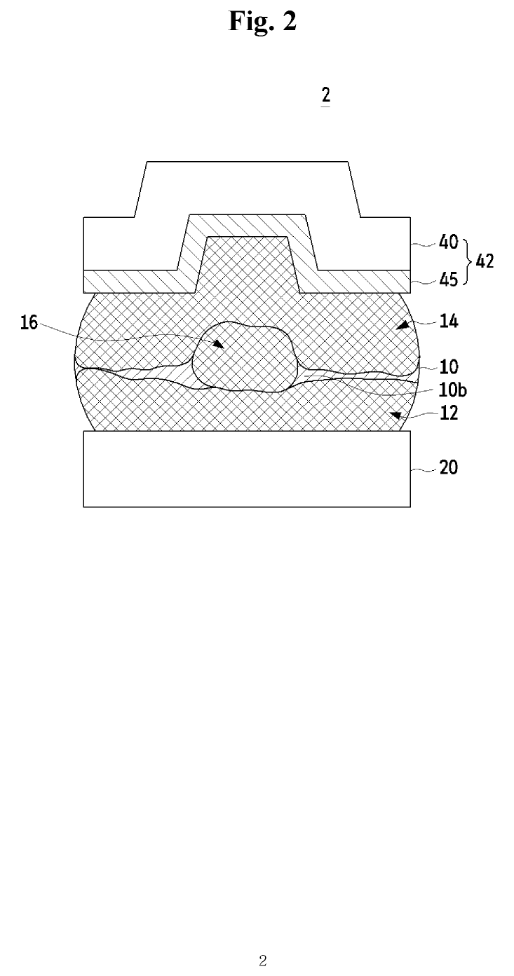

FIG. 2 is a view illustrating a connection structure according to some embodiments of the present disclosure. For convenience of description, the following description will be based on differences from that described with reference to FIG. 1.

In the connection structure 1 shown in FIG. 1, an intermetallic compound containing copper is not formed in the central region 10a of the solder bump 10. The central region 10a of the solder bump 10 may maintain an initial state. For example, the central region 10a of the solder bump 10 may not contain copper or whichever material is used in the anti-shrinkage layers 25/45.

On the other hand, a connection structure 2 shown in FIG. 2 includes not only a first intermetallic compound 12 that is in contact with the pad 20 and a second intermetallic compound 14 that is in contact with the bump connection layer 42, but also a third intermetallic compound 16 formed in the central region of the solder bump 10. The third intermetallic compound 16 is formed by diffusing a material constituting the first anti-shrinkage layer (see reference numeral 25 of FIG. 10) or the second anti-shrinkage layer 45 into the solder bump 10. When the anti-shrinkage material is copper, the third intermetallic compound 16 may contain copper, and may be, for example, a copper-tin compound. For example, the third intermetallic compound 16 may be a Cu-Sn-Ag compound. Though a boundary is depicted between the first intermetallic compound 12 and the third intermetallic compound 16, and between the second intermetallic compound 14 and the third intermetallic compound 16, there may be no discernable boundary, and the different intermetallic compounds may be merged with one another.

An intermetallic compound may not be formed in a region (see reference numeral 10b) among the intermetallic compounds 12, 14, and 16. For example, the initial state of the solder bump 10 may be maintained between the first intermetallic compound 12 and the second intermetallic compound 14, between the second intermetallic compound 14 and the third intermetallic compound 16, or between the first intermetallic compound 12 and the third intermetallic compound 16.

In the solder bump 10, a ratio of the intermetallic compounds 12, 14, and 16 containing copper to the overall solder bump 10 may be 90% or more and 100% or less. In this way, when the intermetallic compounds 12, 14, and 16 containing copper occupy a large region in the solder bump 10, the connection structure does not shrink significantly even though the connection structure is exposed to a high temperature in a subsequent process/test process. In the subsequent process/test process, the material (e.g., nickel) constituting the pad base 20p is largely prevented from permeating into the solder bump 10.

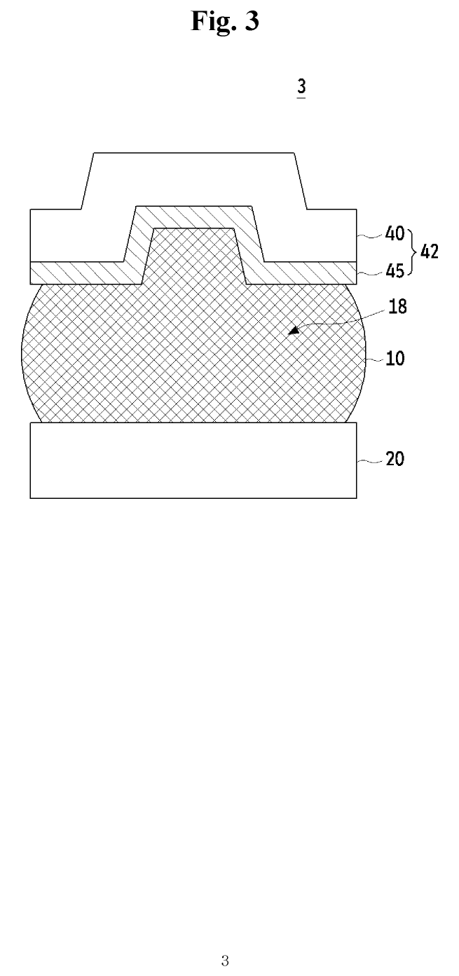

FIG. 3 is a view illustrating a connection structure according to some embodiments of the present disclosure. For convenience of description, the following description will be based on differences from that described with reference to FIG. 1.

Referring to FIG. 3, the entire solder bump 10 may be made of an intermetallic compound 18 containing copper, or containing whichever material is used in the anti-shrinkage layers 25/45. Therefore, even though a connection structure 3 is exposed to a high temperature in a subsequent process/test process, the connection structure 3 does not shrink significantly. In the subsequent process/test process, the material (e.g., nickel) constituting the pad base 20p is largely prevented from permeating into the solder bump 10.

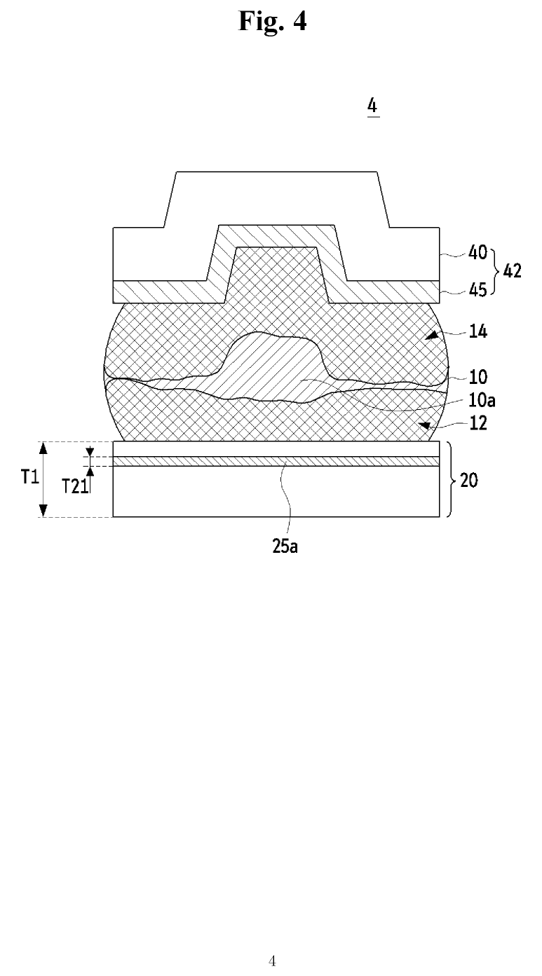

FIG. 4 is a view illustrating a connection structure according to some embodiments of the present disclosure. For convenience of description, the following description will be based on differences from that described with reference to FIG. 1.

Referring to FIG. 4, a portion of the first anti-shrinkage layer 25 used in a process of fabricating a connection structure 4, hereinafter described as a remaining first anti-shrinkage layer 25a, may remain in the pad 20. The first anti-shrinkage layer 25 may be any one of Cu, Fe, and Pb, but is not limited thereto. Hereinafter, a case in which the first anti-shrinkage layer 25 is a copper layer will be described as an example.

A thickness T21 of the remaining first anti-shrinkage layer 25a may be 1% to 40% of a thickness T1 of the pad 20. For example, the thickness T1 of the pad 20 may be 1μm to 2μm, and the thickness of the remaining first anti-shrinkage layer 25a may be 0.1μm to 0.8μm.

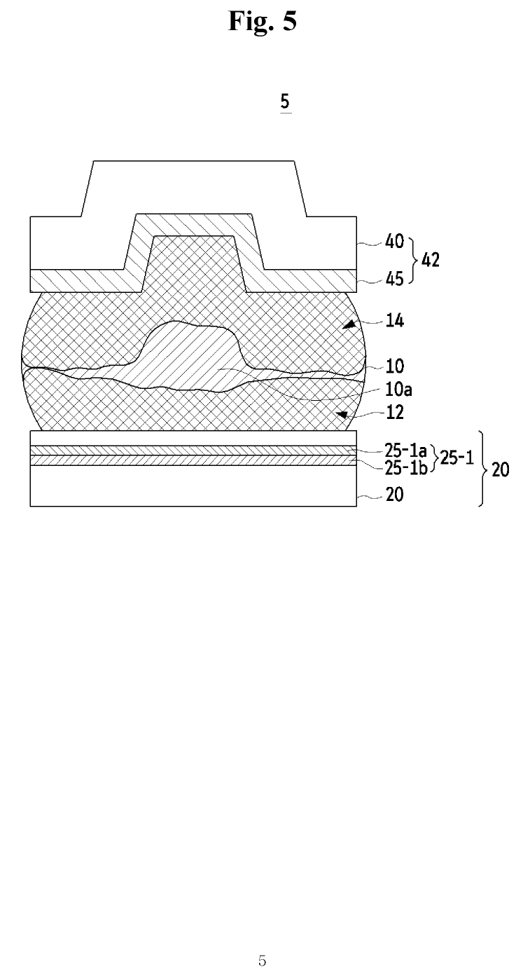

FIG. 5 is a view illustrating a connection structure according to some embodiments of the present disclosure. For convenience of description, the following description will be based on differences from that described with reference to FIGS. 1 and 4.

Referring to FIG. 4, the remaining first anti-shrinkage layer 25a positioned in the pad 20 is a single layer. The remaining first anti-shrinkage layer 25a may be a copper layer.

Referring to FIG. 5, the remaining first anti-shrinkage layer 25-1 positioned in the pad 20 may be provided as a plurality of layers. For example, a case in which the remaining first anti-shrinkage layer 25-1 is provided as two sub-layers 25-1a and 25-1b is shown, but the present disclosure is not limited thereto. The preliminary first anti-shrinkage layer 25-1 (and hence the first anti-shrinkage layer formed prior to manufacturing the solder bump 10) may be provided as three or more layers. The first sub-layer 25-1a may be any one of Cu, Fe, and Pb, and the second sub-layer 25-1b may be any one of Cu, Fe, and Pb. For example, the first sub-layer 25-1a may contain copper (Cu), and the second sub-layer 25-1b may contain iron (Fe). Copper or iron may be permeated into the solder bump 10 to generate an intermetallic compound.

The first intermetallic compound 12 may contain copper and/or iron, and may be, for example, a Cu-Fe-Sn-Ag compound. The second intermetallic compound 14 may contain copper, and may be, for example, a Cu-Sn-Ag compound.

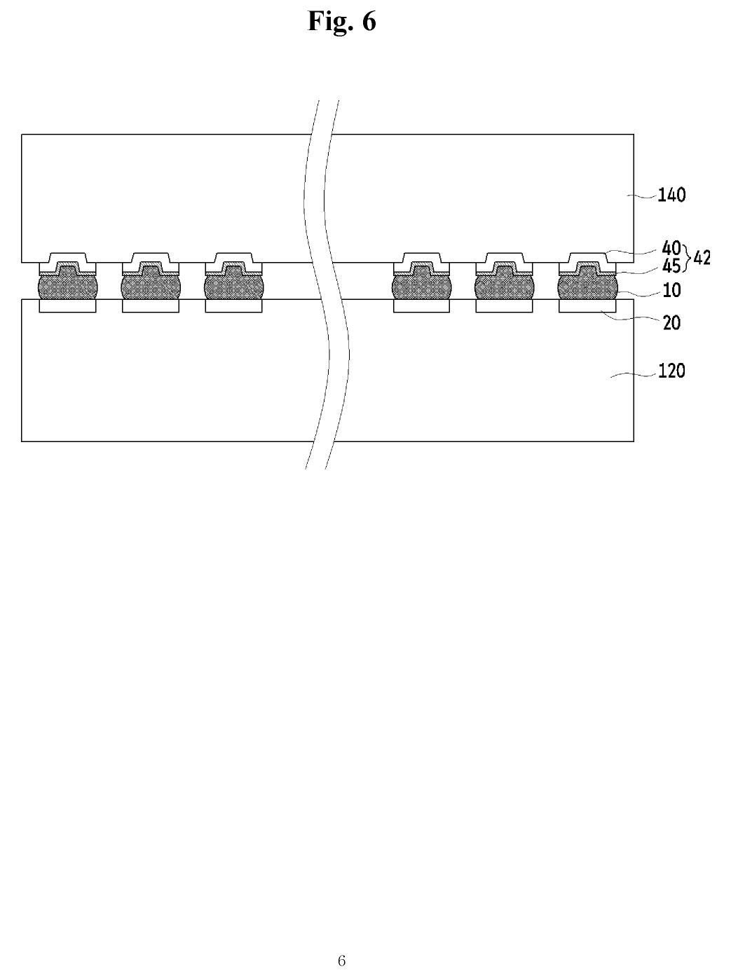

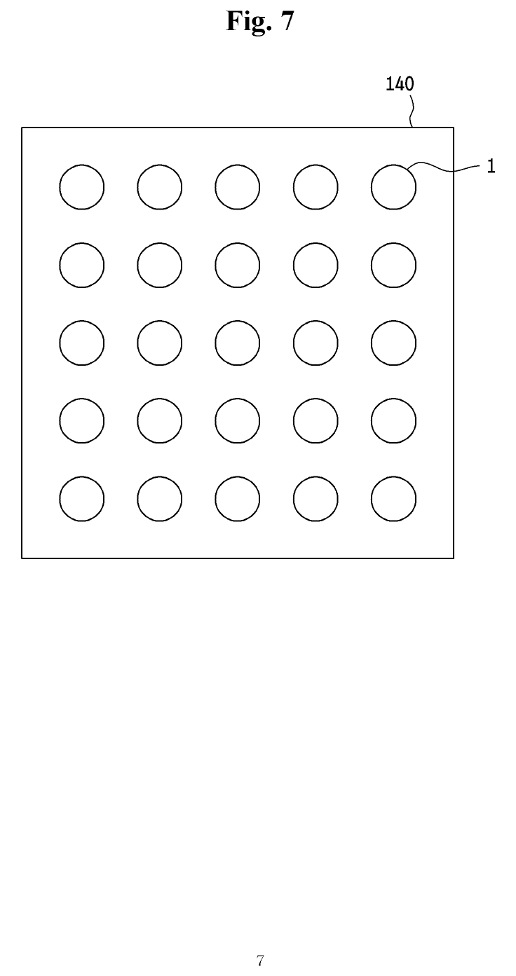

FIG. 6 is a view illustrating a semiconductor device according to some embodiments of the present disclosure. FIG. 7 is a plan view illustrating arrangement of the connection structure of FIG. 6.

First, referring to FIG. 6, the semiconductor device according to some embodiments of the present disclosure includes a first substrate 120, a second substrate 140, and a connection structure 1 (e.g., a plurality of connection structures, with only one being labeled to represent the plurality). The semiconductor device may be, for example, a semiconductor package including a semiconductor chip (e.g., one of the substrates shown) on a package substrate (e.g., the other of the substrates shown), or may be, for example, two substrates such as an interposer substrate formed on a package substrate, or two substrates such as a first semiconductor chip formed on a second semiconductor chip. The connection structure 1 shown in FIG. 1 is shown in FIG. 6, but is not limited thereto. At least one of connection structures 2, 3, 4, and 5 shown in FIGS. 2 to 5 may be used.

The pad 20 is formed on a first surface (for example, a rear surface, which may be an inactive surface opposite to a surface at which active elements such a transistors are formed) of the first substrate 120.

The bump connection layer 42 is formed on a second surface (for example, a front surface, which may be an active surface on which active elements are formed) of the second substrate 140. A plurality of grooves, or recesses, may be formed on the second surface, and the bump connection layer 42 may be formed to be conformal along the grooves. The connection layer 42 may include a bump base 40 formed to be conformal along the grooves and a second anti-shrinkage layer 45 formed to be conformal along the bump base 40.

The solder bump 10 is arranged between the pad 20 and the bump connection layer 42. A first intermetallic compound that is in contact with the pad 20 and contains copper and a second intermetallic compound that is in contact with the bump connection layer 42 and contains copper are positioned in the solder bump 10. The first intermetallic compound may contain a copper-tin intermetallic compound, and the second intermetallic compound may contain a copper-tin intermetallic compound. Also, a copper-tin intermetallic compound may be arranged in a central region of the solder bump. Alternatively, the entire solder bump may be made of a copper-tin intermetallic compound.

A remaining first anti-shrinkage layer (see reference numeral 25a of FIG. 4) may remain in the pad 20. The remaining first anti-shrinkage layer (see reference numeral 25a of FIG. 4) may be any one of Cu, Fe, and Pb, but is not limited thereto.

As shown in FIG. 7, a plurality of connection structures 1 may be arranged in a matrix form with respect to the second substrate 140/the first substrate. The number and/or arrangement of the plurality of connection structures 1 may vary depending on design.

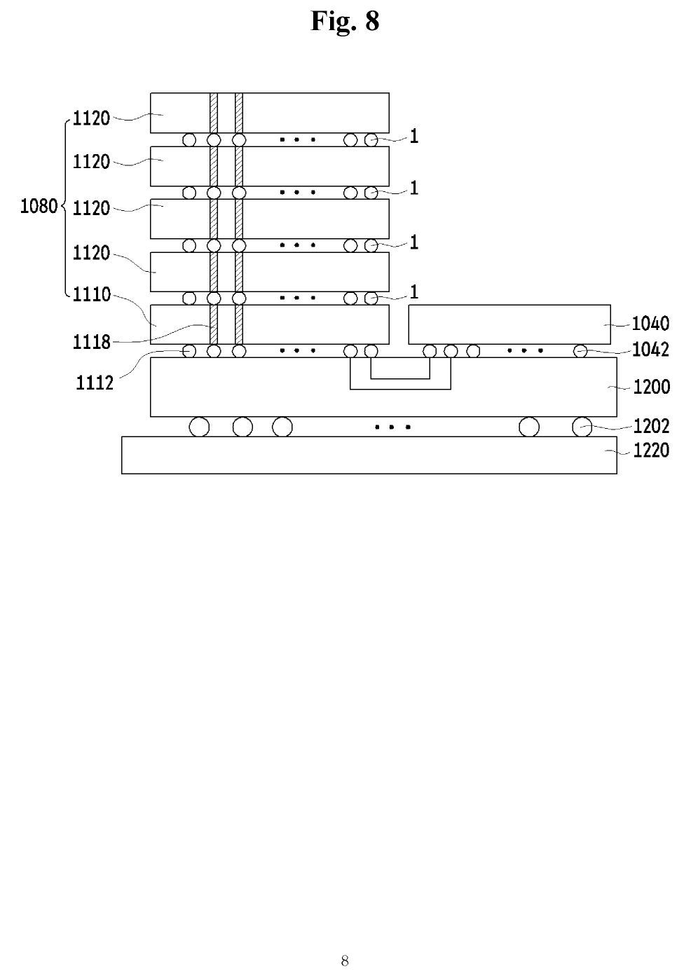

FIG. 8 is a cross-sectional view illustrating a semiconductor package according to some embodiments of the present disclosure. For convenience of description, the following description will be based on differences from that described with reference to FIGS. 1 to 7.

Referring to FIG. 8, the semiconductor package according to some embodiments of the present disclosure may include a plurality of integrated circuit dies. The plurality of integrated circuit dies may be aligned into, for example, a multi-chip module (MCM). The multi-chip module may be an electronic assembly, such as a package including a plurality of conductive terminals or pins, in which a plurality of integrated circuits, semiconductor dies, and/or other distinguished components are integrated on a unifying substrate and regarded as a single component (e.g., a larger IC) in use. Although FIG. 8 exemplarily shows a high bandwidth memory (HBM) device, this is only exemplary.

A semiconductor package 100 according to some embodiments of the present disclosure includes a package substrate 1220, an interposer 1200, a processor 1040, a logic die 1110, and a plurality of memory dies 1120.

The package substrate 1220 may be configured to perform communication with other components or dies and the outside of the semiconductor package. A plurality of balls may be installed on a lower surface of the package substrate 1220, but the present disclosure is not limited thereto.

The interposer 1200 may include silicon or other substrates. A plurality of bumps 1202 may be installed on a lower surface of the interposer 1200, but the present disclosure is not limited thereto. The interposer 1200 may be configured to perform communication between the processor 1040 and the logic die 1110. Also, the interposer 1200 may be configured to enable communicate between the logic die 1110 and the package substrate 1220 and communication between the processor 1040 and the package substrate 1220.

The interposer 1200 may include a first region and a second region, which are adjacent to each other.

The processor 1040 is arranged on the first region of the interposer 1200. The processor 1040 may be configured to execute various instructions or perform logic operations.

A micro-bump 1042 is installed on a lower surface of the processor 1040 to electrically connect the processor 1040 to the interposer 1200.

The processor 1040 may be a central processing unit (CPU), and may include a specialized processing unit such as a graphic processing unit (GPU), an encryption processing unit, a physical processing unit, and a machine learning processing unit. The above examples are simply and partially shown embodiments, and the present disclosure is not limited thereto.

A stack 1080 is arranged on the second region of the interposer 1200. The stack 1080 includes a logic die 1110 and a plurality of stacked memory dies 1120.

The logic die 1110 may be configured to perform standard memory access coordination functions (e.g., page table translations, address mapping, write combination, etc.). In various embodiments, the logic die 1110 may include a memory management unit (MMU) centralized on the plurality of memory dies 1120 but is not limited thereto. Micro-bumps 1112 are installed on a lower surface of the logic die 1110 to electrically connect the logic die 1110 to the interposer 1200.

The plurality of memory dies 1120 may be arranged to be stacked on each other. That is, the memory dies 1120 may have a structure in which one memory die 1120 is stacked on another memory die 1120. The memory die 1120 may be, for example, a DRAM memory die, but is not limited thereto. According to some embodiments, a connection structure 1 is installed on a lower surface of each of the plurality of memory dies 1120 to electrically connect the logic die 1110 to the memory die 1120. Also, the memory dies 1120 stacked up and down may be electrically connected to each other through the connection structure 1.

As described above, the connection structure 1 includes a pad, a bump connection. layer, and a solder bump. In some embodiments, a first intermetallic compound that is in contact with the pad and contains copper and a second intermetallic compound that is in contact with the bump connection layer and contains copper are positioned in the solder bump.

An element formed in the memory die 1120 may be implemented in various forms. For example, the element may be implemented as a Buried Channel Array Transistor Cell (BCAT), a Vertical Channel Transistor (VCT), a Vertical Stack DRAM (VS-DRAM), etc. In addition, SiGe or amorphous oxide (e.g., IGZO(InGaZnO)) as well as silicon may be used as a channel material.

Furthermore, communication between the plurality of memory dies 1120 and the logic die 1110 may be performed through a through electrode (e.g., a through-substrate via (TSV) such as a through-silicon via) and a vertical wiring. As shown, a through electrode 1118 is formed in the logic die 1110 and each memory die 1120.

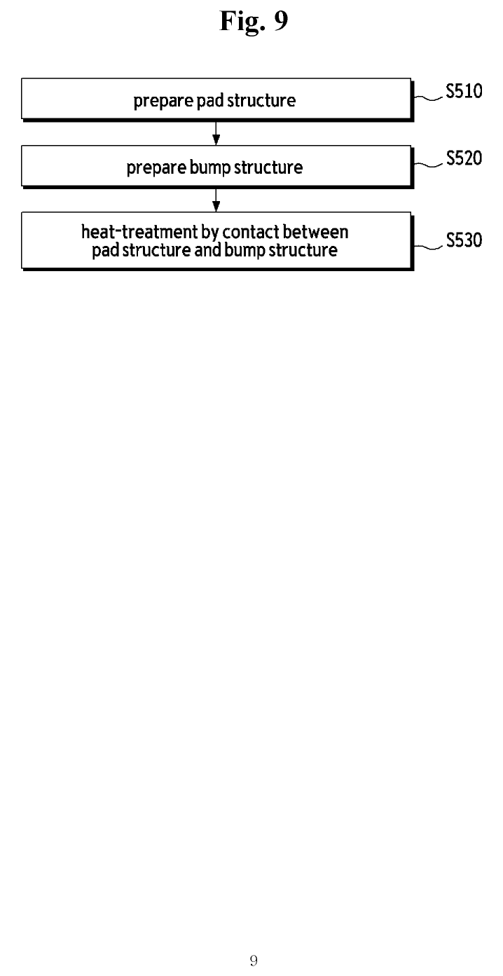

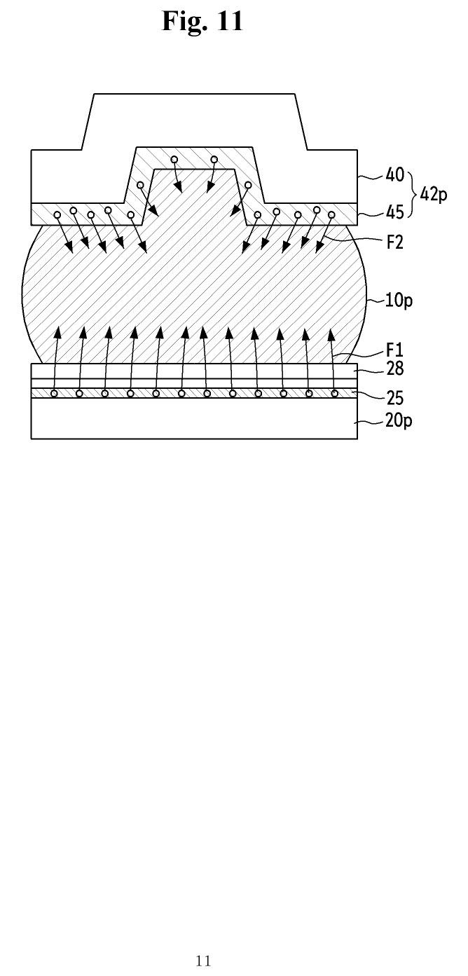

FIG. 9 is a flow chart illustrating a method for fabricating a connection structure according to some embodiments of the present disclosure. FIG. 10 is a view illustrating the method of FIG. 9. FIG. 11 is a view illustrating a step S530 of FIG. 9.

Referring to FIG. 9, a pad structure is prepared (S510). As shown in FIG. 10, the pad structure includes a pad base 20p, a first anti-shrinkage layer 25, and a contact layer 28. The pad base 20p may be made of, for example, Ni, Al, or the like, but is not limited thereto. The first anti-shrinkage layer 25 may be any one of Cu, Fe, and Pb, but is not limited thereto. The material (e.g., copper) constituting the first anti-shrinkage layer 25 may have a faster permeation rate into a preliminary solder bump 10p than the pad base 20p (e.g., nickel). The contact layer 28 may be Au but is not limited thereto. A thickness T1 of the pad base 20p is thicker than a thickness T2 of the first anti-shrinkage layer 25. The thickness T2 of the first anti-shrinkage layer 25 may be 1% to 40% of the thickness T1 of the pad base. The thickness T1 of the pad base may be 1 μm to 2 μm, and the thickness of the first anti-shrinkage layer 25 may be 0.1μm to 0.8μm.

Subsequently, a bump structure is prepared (S520). However, this is just one embodiment, and the order of preparing the bump structure and pad structure may be reversed, or both may occur at the same time. As shown in FIG. 10, the bump structure includes a preliminary bump connection layer 42p and a solder bump 10. The preliminary bump connection layer 42p includes a preliminary bump base 40p and a preliminary second anti-shrinkage layer 45p. The preliminary bump base 40p may be made of, for example, Ni, Al, or the like, but is not limited thereto. The preliminary second anti-shrinkage layer 45p may be any one of Cu, Fe, and Pb, but is not limited thereto. In one embodiment, a thickness of the preliminary second anti-shrinkage layer 45p is greater than that of the preliminary first anti-shrinkage layer 25p. The preliminary solder bump 10p may contain tin, and for example, may contain Sn, SnAg, Sn-Pb, SnAgZn, SnZn, SnBiIn, SnIn, SnAu, SnZnIn, or SnAgSb, but is not limited thereto.

Subsequently, the pad structure and the bump structure are brought into contact with each other to perform heat treatment (S510).

In detail, as shown in FIG. 11, copper is permeated and flows into the preliminary solder bump 10p from the first anti-shrinkage layer 25 by heat treatment (see F1). Accordingly, a first intermetallic compound (see 12 of FIG. 1) which is in contact with the pad 20 and contains copper is formed in the completed solder bump 10.

Copper is permeated and flows into the preliminary solder bump 10p from the preliminary second anti-shrinkage layer 45p (see F2) as well. Accordingly, a second intermetallic compound (see 14 of FIG. 1) which is in contact with the bump connection layer 42 (e.g., and therefore is in contact with the completed second anti-shrinkage layer 45) and contains copper is formed in the completed solder bump 10.

Although the embodiments of the present disclosure have been described with reference to the accompanying drawings, it will be apparent to those skilled in the art that the present disclosure may be fabricated in various forms without being limited to the above-described embodiments and may be embodied in other specific forms without departing from the technical spirit and essential characteristics. Thus, the above embodiments are to be considered in all respects as illustrative and not restrictive.

What is claimed is:

1. A conductive interconnection node for a semiconductor device, the conductive interconnection node comprising:
a pad containing nickel;
a bump connection layer containing nickel; and
a solder bump arranged between the pad and the bump connection layer,
wherein the solder bump includes:
a first intermetallic compound contacting the pad and containing copper; and
a second intermetallic compound contacting the bump connection layer and containing copper.

2. The conductive interconnection node of claim 1, wherein the first intermetallic compound is a copper-tin intermetallic compound.

3. The conductive interconnection node of claim 2, wherein the second intermetallic compound is a copper-tin intermetallic compound.

4. The conductive interconnection node of claim 3, further comprising an additional copper-tin intermetallic compound formed in a central region of the solder bump.

5. The conductive interconnection node of claim 3, wherein the entire solder bump is made of a copper-tin intermetallic compound.

6. The conductive interconnection node of claim 1, further comprising a first copper layer in the pad.

7. The conductive interconnection node of claim 6, wherein the bump connection layer includes a second copper layer and a bump base, the second copper layer arranged between the bump base and the solder bump.

8. The conductive interconnection node of claim 7, wherein the second copper layer is thicker than the first copper layer.

9. A semiconductor device comprising:
a first substrate;
a second substrate arranged on the first substrate; and
a conductive interconnection node electrically connecting the first substrate to the second substrate,
wherein the conductive interconnection node includes:
a pad formed in the first substrate and containing nickel,
a bump connection layer formed in the second substrate and containing nickel, and
a solder bump arranged between the pad and the bump connection layer, the solder bump including:
a first intermetallic compound contacting the pad and containing copper, and
a second intermetallic compound contacting the bump connection layer and containing copper.

10. The semiconductor device of claim 9, wherein the first intermetallic compound is a copper-tin intermetallic compound, and the second intermetallic compound is a copper-tin intermetallic compound.

11. The semiconductor device of claim 10, wherein a volume ratio of the combined first intermetallic compound and second intermetallic compound to a total volume of the solder bump is 70% or more and 100% or less.

12. The semiconductor device of claim 10, wherein the entire solder bump is made of a copper-tin intermetallic compound.

13. The semiconductor device of claim 9, further comprising a first copper layer in the pad.

14. The semiconductor device of claim 13, wherein the bump connection layer includes a second copper layer and a bump base, the second copper layer arranged between the bump base and the solder bump.

15. The semiconductor device of claim 14, wherein the second copper layer is thicker than the first copper layer.

16. The semiconductor device of claim 9, further comprising a through substrate via connected to the pad in the first substrate.

17. A semiconductor device comprising:
a package substrate;
a logic die arranged on the package substrate;
a plurality of memory dies sequentially stacked on the logic die,
wherein the plurality of memory dies include a first die and a second die, which are stacked; and
a conductive connection node between and electrically connecting the first die to the second die,
wherein the conductive connection node includes:
a pad formed at a surface of the first die and containing nickel,
a bump connection layer formed at a surface of the second die and containing nickel, and
a solder bump arranged between the pad and the bump connection layer, wherein the solder bump includes:
a first intermetallic compound portion including a first intermetallic compound including copper and contacting the pad, and
a second intermetallic compound portion including the first intermetallic compound including copper or a second intermetallic compound including iron or lead, and contacting the bump connection layer.

18. The semiconductor device of claim 17, wherein the first intermetallic compound portion contains a copper-tin intermetallic compound, and the second intermetallic compound portion contains a copper-tin intermetallic compound.

19. The semiconductor device of claim 17, wherein a volume ratio of the combined first intermetallic compound portion and second intermetallic compound portion to a total volume of the solder bump is 70% or more and 100% or less.

20. The semiconductor device of claim 17, further comprising a first copper layer in the pad, and a second copper layer in the bump connection layer, wherein the bump connection layer includes the second copper layer and a bump base, the second copper layer arranged between the bump base and the solder bump,
wherein the second copper layer is thicker than the first copper layer.
